(19) United States
(12) Patent Application Publication
(10) Pub. No.: US 2024/0241401 A1
(43) Pub. Date: Jul. 18, 2024

(54) DISPLAY DEVICE

(71) Applicant: SIC Technology CO. LTD, Hsinchu City (TW)

(72) Inventor: Shien-Tsung WU, Hsinchu City (TW)

(21) Appl. No.: 18/435,849

(22) Filed: Feb. 7, 2024

Related U.S. Application Data
(63) Continuation-in-part of application No. 17/338,257, filed on Jun. 3, 2021, now Pat. No. 11,898,744.
Application No. 17/338,257 is a continuation-in-part of application No. 16/332,322, filed on Mar. 11, 2019, now abandoned.

(30) Foreign Application Priority Data
Sep. 13, 2016 (TW) 105129771
Nov. 15, 2016 (TW) 105137238

(51) Int. Cl. G02F 1/1335; G02F 1/13357; H01L 33/50

(52) U.S. Cl. CPC G02F 1/133514; G02F 1/133614; G02F 1/133615; H01L 33/502

(57) ABSTRACT

A display device includes a liquid crystal adjustment unit, a color filter structure, a light-emitting unit, and an excitation layer. The color filter structure includes an RGB color filter layer. The RGB color filter layer has red, blue, and green color filters arranged in a matrix. The light-emitting unit is disposed on the liquid crystal adjustment unit and includes a first and a second light-emitting element emitting respectively emitting blue light and red light. The excitation layer is spaced apart from the light-emitting unit and includes quantum structures that are registered with the green color filters, that are quantum dots or quantum rods, and that are made of cesium lead halide or organic ammonium lead halide.

### CROSS-REFERENCE TO RELATED APPLICATION

This is a continuation-in-part application of U.S. patent application Ser. No. 17/338,257, filed on Jun. 3, 2021, which is a continuation-in-part (CIP) application of U.S. patent application Ser. No. 16/332,322 having a National Phase Entry date of Mar. 11, 2019, which is a national stage application under 35 U.S.C. 371 of PCT International Application No. PCT/IB2017/054934, filed on Aug. 14, 2017, which claims priority of Taiwanese Invention Patent Application No. 105129771, filed on Sep. 13, 2016, and Taiwanese Invention Patent Application No. 105137238, filed on Nov. 15, 2016, the entire content of each of which is incorporated herein by reference.

### FIELD

The disclosure relates to a display device, and more particularly to a display device with an excitation layer.

### BACKGROUND

A conventional quantum structure light-emitting module includes a light-emitting unit and a quantum structure thin film that includes a plurality of quantum dots. The light-emitting unit emits a first light to excite the quantum structure thin film so as to emit a second light, which mixes with the first light to form a desired output light. For example, a blue light-emitting unit emits a blue light to excite the quantum dots so as to emit a red light and a green light, which mix with the blue light to form a white light. The light response property of the quantum dots can be adjusted by changing the size or material of the quantum dots.

The quantum structure light-emitting module can be used in a backlight module of a display device. The display device including the quantum structure light-emitting module has superior color level, chromaticity, color gamut, and color saturation.

Conventionally, cadmium-containing semiconductor materials, such as cadmium sulfide, cadmium selenide, cadmium telluride, etc., are widely used for making the quantum dots. However, the toxic nature of the cadmium-containing semiconductor materials has driven scientists to seek for alternative materials, such as CsPbX3, in which X can be fluorine, bromine, iodine, or combinations thereof. The light emitted by the quantum dots might be altered by changing the ratio of fluorine, bromine, and iodine, or by changing the size of the quantum dots. A blue-light-emitting unit is often used for exciting the CsPbX3 quantum dots to obtain red and green lights. However, such excitation mechanism has a problem of insufficient amount of red light, resulting in inferior color gamut of the display device.

Moreover, the quantum structure thin film, when operated for a long time, is susceptible to overheating which might result in bowing thereof.

### SUMMARY

Therefore, an object of the disclosure is to provide a display device that can alleviate at least one of the drawbacks of the prior art.

According to the disclosure, the display device includes a liquid crystal adjustment unit, a color filter structure, a light-emitting unit, and an excitation layer. The liquid crystal adjustment unit includes a liquid crystal layer and an electrode layer disposed on the liquid crystal layer. The color filter structure is disposed on the liquid crystal adjustment unit, and includes an RGB color filter layer. The RGB color filter layer has a plurality of red color filters, a plurality of blue color filters, and a plurality of green color filters that are spaced apart from each other, and arranged in a matrix pattern. The light-emitting unit is disposed on the liquid crystal adjustment unit opposite to the RGB color filter layer and includes a first light-emitting element emitting a blue light and a second light-emitting element emitting a red light. The excitation layer is disposed between the color filter structure and the light-emitting unit, is spaced apart from the light-emitting unit and includes a plurality of quantum structures. The quantum structures are registered with the green color filters, are one of quantum dots and quantum rods, and are made of one of cesium lead halide and organic ammonium lead halide.

### BRIEF DESCRIPTION OF THE DRAWINGS

Other features and advantages of the disclosure will become apparent in the following detailed description of the embodiment(s) with reference to the accompanying drawings. It is noted that various features may not be drawn to scale.

FIG. 1 is a fragmentary cross-sectional side view illustrating a first embodiment of a quantum structure light-emitting module according to the disclosure;

FIG. 2 is a fragmentary cross-sectional side view illustrating a second embodiment of the quantum structure light-emitting module according to the disclosure;

FIG. 3 is a fragmentary cross-sectional side view illustrating a third embodiment of the quantum structure light-emitting module according to the disclosure;

FIG. 4 is a fragmentary cross-sectional side view illustrating a fourth embodiment of the quantum structure light-emitting module according to the disclosure;

FIG. 5 is a fragmentary cross-sectional side view illustrating a fifth embodiment of the quantum structure light-emitting module according to the disclosure; and

FIG. 6 is a fragmentary schematic view of the fifth embodiment, showing relative position of a light-emitting unit and a light guide plate of the fourth embodiment.

FIG. 7 is a schematic cross-sectional side view illustrating an embodiment of a display device of the present disclosure.

FIG. 8 is a schematic cross-sectional side view illustrating a variation of the embodiment of the display device.

FIG. 9 is a schematic cross-sectional side view illustrating another variation of the embodiment of the display device.

FIG. 10 is a schematic cross-sectional side view illustrating yet another variation of the embodiment of the display device.

FIG. 11 is a schematic cross-sectional side view illustrating further yet another variation of the embodiment of the display device.

### DETAILED DESCRIPTION

Before the disclosure is described in greater detail, it should be noted that where considered appropriate, reference numerals or terminal portions of reference numerals have been repeated among the figures to indicate corresponding or analogous elements, which may optionally have similar characteristics.

It should be noted herein that for clarity of description, spatially relative terms such as “top,” “bottom,” “upper,” “lower,” “on,” “above,” “over,” “downwardly,” “upwardly” and the like may be used throughout the disclosure while making reference to the features as illustrated in the drawings. The features may be oriented differently (e.g., rotated 90 degrees or at other orientations) and the spatially relative terms used herein may be interpreted accordingly.

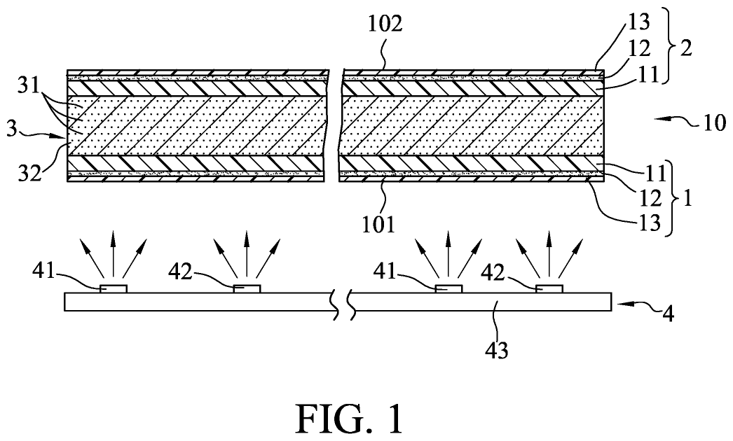

Referring to FIG. 1, a first embodiment of a quantum structure light-emitting module according to the present disclosure includes a quantum structure thin film 10 and a light-emitting unit 4. The quantum structure light-emitting module of this disclosure may be used in a display device (not shown in figures).

The quantum structure thin film 10 includes an excitation layer 3, a first substrate 1 and a second substrate 2.

The first substrate 1 and the second substrate 2 are respectively disposed on two opposite sides of the excitation layer 3. The first substrate 1 has an incident surface 101 opposite to the excitation layer 3, and the second substrate 2 has a light exiting surface 102 opposite to the excitation layer 3. At least one of the first substrate 1 and the second substrate 2 has a multi-layered structure which includes an inner layer 11, a buffer layer 12, and an outer layer 13 that are sequentially disposed on the excitation layer 3 in such order. In certain embodiments, one of the first substrate 1 and the second substrate 2 has the abovementioned multi-layered structure, and the other one of the first substrate 1 and the second substrate 2 has a single-layer structure which includes only the inner layer 11.

Alternatively, in this embodiment, each of the first substrate 1 and the second substrate 2 has the abovementioned multi-layered structure. The inner layers 11 and the outer layers 13 of the first and second substrate 1, 2 may be independently made of polyethylene terephthalate (PET), cyclic olefin copolymer (COC), polyimide (PI), polyethersulfone (PES), polyethylene naphthalate (PEN), polycarbonate (PC), and combinations thereof. The material for making the inner layer 11 of the first substrate 1 may be identical to or different from the material for making the inner layer 11 of the second substrate 2. Also, the material for making the outer layer 13 of the first substrate 1 may be identical to or different from the material for making the outer layer 13 of the second substrate 2. Each of the inner layers 11 may have a thickness ranging from 8 μm to 15 μm. Each of the outer layers 13 may have a thickness ranging from 30 μm to 45 μm.

For each of the first substrate 1 and the second substrate 2, the buffer layer 12 may be made of an optically clear adhesive. The buffer layer 12 may have a thickness ranging from 8 μm to 12 μm. The buffer layer 12 is configured to increase the mechanical strength of the quantum structure thin film 10, so that the quantum structure thin film 10 may be use in a display device with a relatively larger area. It is noted that overheating of the quantum structure thin film 10 caused by continuously operating it for a long time would induce deformation of the inner layer(s) 11 and the outer layer(s) 13, which if present, may result in bowing of the quantum structure thin film 10. In such case, the buffer layer 12 may serve as a heat buffer layer to reduce such bowing of the quantum structure thin film 10.

The excitation layer 3 includes a main body 32 and a plurality of quantum structures 31 distributed in the main body 32. The quantum structures 31 are excitable by a blue light incident thereon to emit a green light. The quantum structures 31 may be one of quantum dots and quantum rods. When the quantum structures 31 are quantum dots, the quantum structures 31 may each have a dimension ranging from 3 nm to 13 nm (e.g., 9 nm to 13 nm), such that the green light emitted thereby is close to pure green, allowing the display device to have superior color gamut. The quantum structures 31 may be made of a perovskite material, which may include, but is not limited to, cesium lead halide and organic ammonium lead halide. In this embodiment, the cesium lead halide is CsPbBr3, and the organic ammonium lead halide is CH3NH3PbBr3. By using the abovementioned perovskite material, the quantum structures 31 are free of cadmium so as to be environmentally friendly.

When making the excitation layer 3, the perovskite materials are immersed into an oleic acid solution or an oleylamine solution that has a predetermined concentration for a predetermined period so as to obtain the quantum structures 31 with desired dimensions. The oleic acid solution and the oleylamine solution serve as stabilizers to improve light stability of the quantum structures 31. The resultant quantum structures 31 are then distributed in a colloidal system which may be made of a light-transmissible resin, and which may serve as a light homogenizer. The colloidal system with the quantum structures 31 may be then coated on the first substrate 1 and/or the second substrate 2, so as to form the main body 32 distributed with the quantum structures 31. Based on actual requirements, the excitation layer 3 may be subjected to an annealing process so as to change the bandgap and to reduce lattice defects of the quantum structures 31, thereby improving light efficiency of the excitation layer 3.

The light-emitting unit 4 is spaced apart from the quantum structure thin film 10. The light-emitting unit 4 includes a circuit board 43, and a plurality of first light-emitting elements 41 and a plurality of second light-emitting elements 42 that are alternatingly arranged on the circuit board 43. Each of the first light-emitting elements 41 may be a blue light-emitting diode that is capable of emitting a blue light. Each of the second light-emitting elements 42 may be a red light-emitting diode that is capable of emitting a red light. In certain embodiments, each of the second light-emitting elements 42 may include potassium fluorosilicate phosphor (KSF), which may be, but is not limited to, K2SiF6:Mn4+phosphor, which allows the second light-emitting element 42 to emit the red light with narrow full width at half maximum (FWHM) of its light emission spectrum, and with high energy, such that the color gamut of the display device is further improved.

In this embodiment, each of the first light-emitting elements 41 and each of the second light-emitting elements 42 are located within a projection of the quantum structure thin film 10 on the light-emitting unit 4. That is, the first embodiment is configured as a direct-lit quantum structure light-emitting module, where the first light-emitting elements 41 and the second light-emitting elements 42 face the incident surface 102 of the first substrate 1.

In use, the blue light emitted from the first light-emitting elements 41 and the red light emitted from the second light-emitting elements 42 pass through the first substrate 1 from the incident surface 101 and enter the excitation layer 3. The blue light excites the quantum structures 31 to emit a green light. The green light emitted form the quantum structures 31 may have a dominant wavelength ranging from 520 nm to 540 nm. The green light emitted from the quantum structures 31, and the blue light and the red light emitted from the light-emitting unit 4 are mixed to form a white light and exit through the second substrate 2 from the light exiting surface 102.

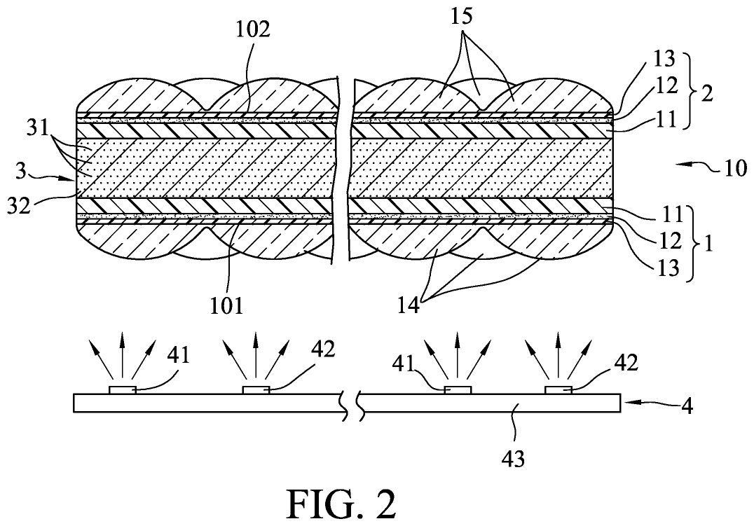

In certain embodiments, at least one of the first substrate 1 and the second substrate 2 may be formed with a plurality of microstructures opposite to the excitation layer 3. For example, referring to FIG. 2, a second embodiment of the quantum structure light-emitting module according to the present disclosure is generally similar to the first embodiment, except that in the second embodiment, the first substrate 1 is further formed with a plurality of first microstructures 14 opposite to the excitation layer 3, and the second substrate 2 is further formed with a plurality of second microstructures 15 opposite to the excitation layer 3. That is, the first and second microstructures 14, 15 are respectively formed on the outer layer 13 of the first substrate 1 and the outer layer 13 of the second substrate 2. The first microstructures 14 and the second microstructures 15 may improve light diffusion and light homogenization of the second embodiment. The first microstructures 14 and the second microstructures 15 may be independently made of poly(methyl methacrylate) (acrylic), polyurethane (PU), silicone, and combinations thereof. The shape of each of the first microstructures 14 and the second microstructures 15 may be identical to or different from each other, and may be conical, semicircular, hexagonal, or irregular, but is not limited thereto. The first microstructures 14 refract the light emitted from the light emitting unit 4, which increases the number of optical paths of the blue light in the excitation layer 3, so as to more effectively excite the quantum structures 31 to emit green light more effectively, thereby allowing the display device to achieve improved color gamut and color saturation. The second microstructures 15 reduce total internal reflection of exiting light, thereby improving light extraction efficiency of the second embodiment.

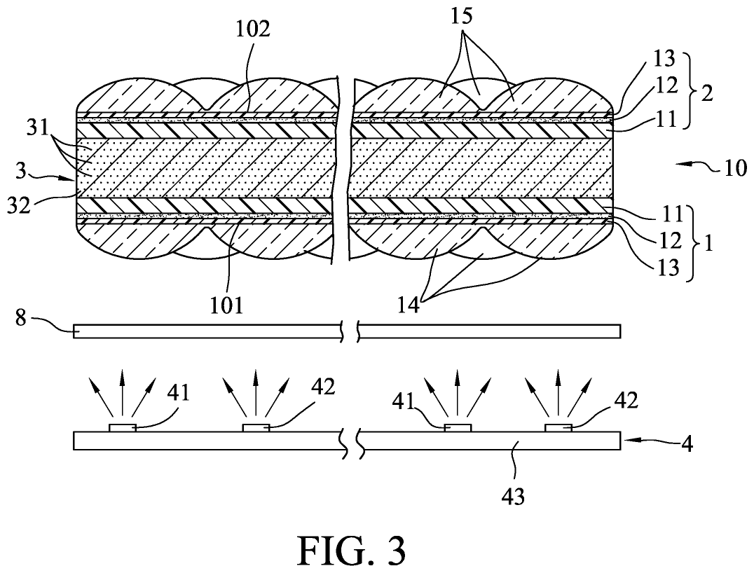

Referring to FIG. 3, a third embodiment of the quantum structure light-emitting module according to the present disclosure is generally similar to the second embodiment, except that the third embodiment further includes a diffusion sheet 8 disposed between the light-emitting unit 4 and the quantum structure thin film 10. The diffusion sheet 8 has a haze that is larger than 60%, so as to achieve an improved softness and uniformity of light, as well as improved light diffusion. Alternatively, the diffusion sheet may also be disposed on the quantum structure thin film 10 opposite to the light-emitting unit 4.

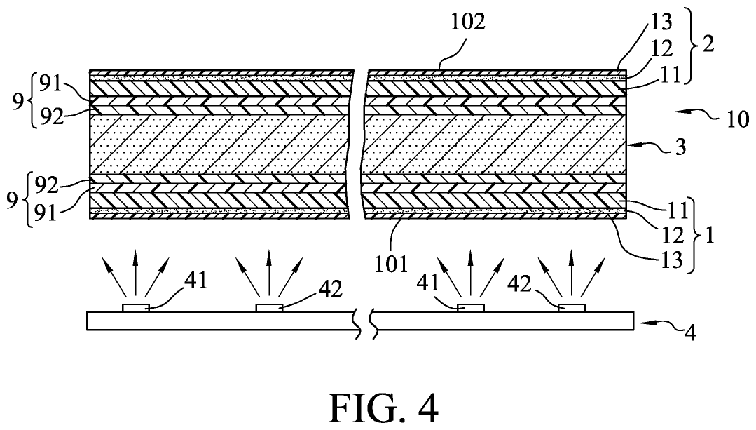

Referring to FIG. 4, a fourth embodiment of the quantum structure light-emitting module according to the present disclosure is generally similar to the first embodiment, except that the fourth embodiment further includes two water resistance units 9 that are respectively disposed between the excitation layer 3 and the first substrate 1 and disposed between the excitation layer 3 and the second substrate 2. Each of the water resistance units 9 includes a water resistance layer 91 and a combination layer 92.

The water resistance layers 91 of the water resistance units 9 are respectively formed on the inner layer 11 of the first substrate 1 and the inner layer 11 of the second substrate 2. The water resistance layer 91 of each of the water resistance units 9 is made of an organic material and an inorganic material, and is moisture impermeable. The organic material may be hexamethyldisiloxane. The inorganic material may be one of metal nitride, metal oxide and metal nitrogen oxide. The water resistance layer 91 of each of the water resistance units 9 has a thickness ranging from 5 nm to 200 nm, and can prevent the moisture from penetrating through the first substrate 1 and the second substrate 2 and affecting the excitation layer 3.

The combination layer 92 of each of the water resistance units 9 is disposed between the excitation layer 3 and the water resistance layer 91 of each of the resistance units 9, and is made of an organic material. In certain embodiments, the combination layer 92 of each of the water resistance units 9 is made of methyl methacrylate, epoxy methacrylate, epoxy acrylates, bisphenol A ethoxylate dimethacrylate, hexanediol diacrylate, bisphenol A epoxy acrylate, and combinations thereof. The combination layers 92 of the water resistance units 9 function to increase adhesion between the water resistance layers 91 of the water resistance units 9 and the excitation layer 3, and also may prevent moisture from penetrating through the first substrate 1 and the second substrate 2. The combination layer 92 of each of the water resistance units 9 has a thickness of around 1 μm.

The combination layers 92 of the water resistance units 9 are formed by coating and thermal curing. The water resistance layers 91 of the water resistance units 9 are formed by a sputtering technique. It is worth mentioning that the bonding formed between the organic and inorganic materials during sputtering may ensure that the water resistance layers 91 are less likely to crack, thereby providing superior water-resistant property.

Moisture may adversely affect the service life of the quantum structure light-emitting module. After long-term exposure to moisture, the efficiency of the excitation layer 3 may be decreased due to cracking. The water resistance layers 91 and the combination layers 92 of the water resistance units 9 not only attach well to the excitation layer 3, but provide a water-resistant property to the excitation layer 3. In addition, the overall thickness of the water resistance units 9 are controlled so as not to add too much volume to the quantum structure light-emitting module.

It should be noted that, based on practical requirements, one of the water resistance units 9 may be omitted. The water resistance units 9 may also be adapted to the second embodiment, where the water resistance units 9 may be respectively disposed between the first microstructures 14 and the excitation layer 3, and between the second microstructures 15 and the excitation layer 3.

In case of the first substrate 1 and/or the second substrate 2 having a multi-layered structure, only the inner layer 11 is placed in a reaction chamber which is subjected to evacuation, followed by formation of the water resistance unit 9 on the inner layer 11 in vacuum, and then the buffer layer 12 and the outer layer 13 may be disposed on and bonded to the inner layer 11 opposite to the water resistance unit 9 outside the reaction chamber. In such a manner, the quantum structure light-emitting module can be manufactured economically and time efficiently.

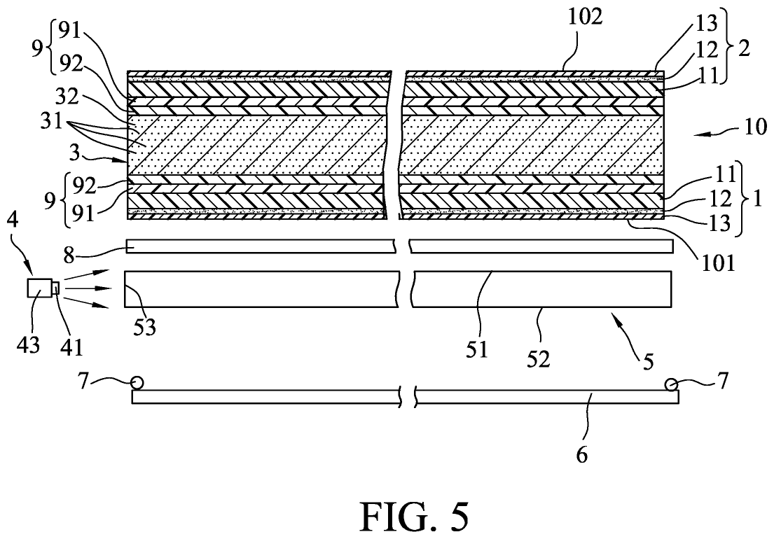

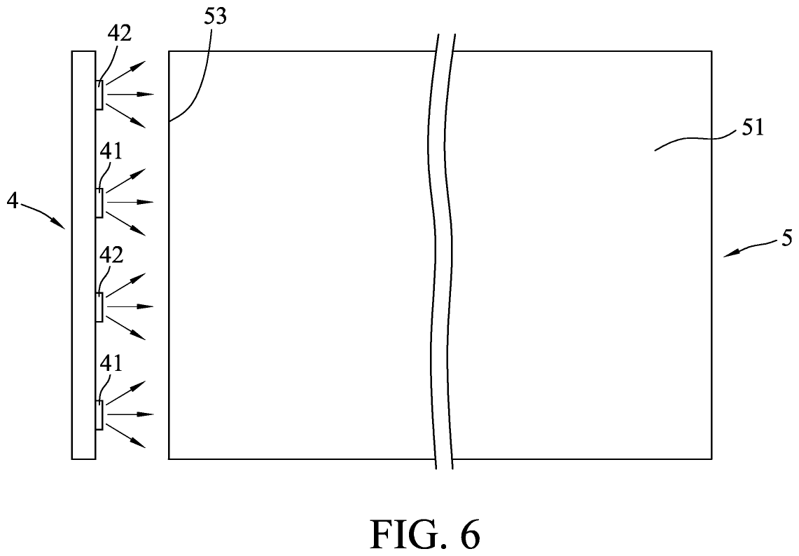

Referring to FIGS. 5 and 6, a fifth embodiment of the quantum structure light-emitting module according to the present disclosure is similar to the first embodiment, except that the fifth embodiment is configured as an edge-lit quantum structure light-emitting module, and further includes a light guide plate 5 that is disposed on a side of the incident surface 101 of the first substrate 1.

The light guide plate 5 has a light exiting light guide surface 51 facing the incident surface 101 of first substrate 1, a reflection light guide surface 52 opposite to the light exiting light guide surface 51, and an incident light guide surface 53 interconnecting the light exiting light guide surface 51 and the reflection light guide surface 52. The reflection light guide surface 52 may be formed with a dot array structure, and is capable of reflecting light. In this embodiment, the first light-emitting elements 41 and the second light-emitting elements 42 are alternatingly arranged along a side of the incident light guide surface 53 of the light guide plate 5 (see FIG. 5), and face the incident light guide surface 53.

The blue light emitted by each of the first light-emitting elements 41 and the red light emitted by each of the first light-emitting elements 42 enter the light guide plate 5 through the incident light guide surface 53, and are directed toward the light exiting light guide surface 51 by the reflection light guide surface 52. After exiting the light exiting light guide surface 51, the blue and red lights enter the quantum structure thin film 10 through the incident surface 101.

The quantum structure light-emitting module may further include a reflective sheet 6 and a green phosphor 7. The reflective sheet 6 is disposed on the reflection light guide surface 52 of the light guide plate 5 to reflect light leaking through the reflection light guide surface 52 back to the light guide plate 5, so as to reduce light loss and improve the brightness of the quantum structure light-emitting module. The green phosphor 7 may be disposed on the reflective sheet 6. The red and/or blue lights leaking through the reflection light guide surface 52 can excite the green phosphor 7 to emit a green light, which is then directed toward the light guide plate 5 by the reflective sheet 6. As such, a total amount of green light exiting the quantum structure thin film 10 (i.e., the green light emitted by the green phosphor 7 and the quantum structures 31) can be increased, and the problem of an undesired color (such as magenta color) being present in the corners and edges of a conventional edge-lit display panel can be thus effectively reduced.

The quantum structure light-emitting module may further include a diffusion sheet 8 disposed between light guide plate 5 and the quantum structure thin film 10. The diffusion sheet 8 may have a haze that is larger than 60%.

The quantum structure light-emitting module may further include at least one water resistance unit 9 as described in the fourth embodiment that is disposed between the excitation layer 3 and one of the first substrate 1 and the second substrate 2.

To sum up, the quantum structure light-emitting module of this disclosure utilizes the blue light emitted by the first light-emitting elements 41 to excite the quantum structures 31 so as to emit the green light. The green light is mixed with the blue light emitted from the first light-emitting elements 41 and the red light emitted from the second light-emitting elements 42 to form the white light, which differs from a conventional light-emitting module that generates red light by using blue light excitation. The quantum structure light-emitting module of this disclosure has a relatively stronger red light intensity, thereby allowing the display device including the quantum structure light-emitting module to have superior color gamut, color saturation and to display white light with a higher intensity. When the second light-emitting elements 42 include K2SiF6:Mn4+phosphor, the color gamut and the color saturation of the display device are further improved. Moreover, by including the buffer layer 12 in each of the first substrate 1 and/ or the second substrate 2, quantum structure thin film 10 may have an improved strength, and a reduced chance of deformation due to overheating.

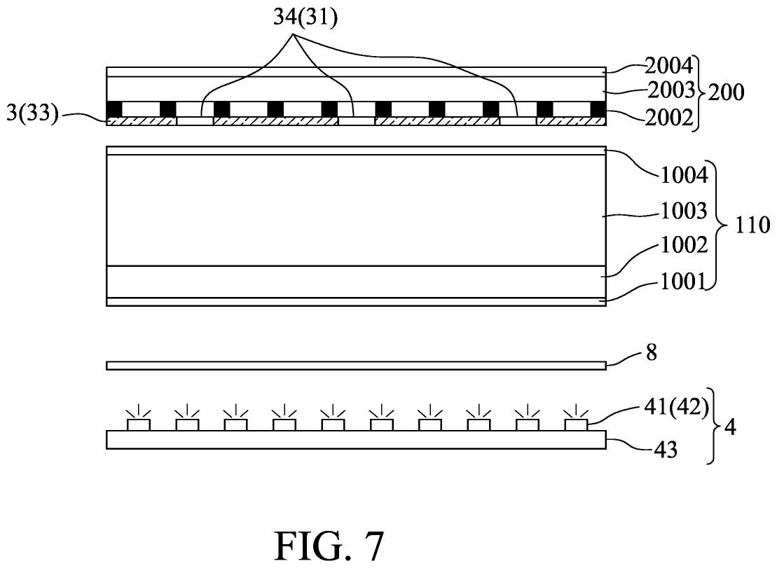

Referring to FIG. 7, an embodiment of a display device of the disclosure includes a liquid crystal adjustment unit 110, a color filter structure 200, an excitation layer 3, and a light-emitting unit 4. In certain embodiments, the color filter structure 200 is disposed on the liquid crystal adjustment unit 110, the light-emitting unit 4 is disposed on the liquid crystal adjustment unit 110 opposite to the color filter structure 200, and the excitation layer 3 is disposed between the color filter structure 200 and the light-emitting unit 4. In this embodiment, the excitation layer 3 is disposed between the color filter structure 200 and the liquid crystal adjustment unit 110, being immediately adjacent to the color filter structure 200.

The liquid crystal adjustment unit 110 includes a liquid crystal layer 1003 and an electrode layer 1004 disposed on the liquid crystal layer 1003. The color filter structure 200 includes an RGB color filter layer 2002, a glass panel layer 2003, and an upper polarization layer 2004. The RGB color filter layer 2002 has a plurality of red color filters, a plurality of blue color filters, and a plurality of green color filters that are spaced apart from each other, and arranged in a matrix pattern. The excitation layer 3 has a structure the same as those described in the aforesaid embodiments, and includes a plurality of the quantum structures 31. The quantum structures 31 are registered with the green color filters of the RGB color filter layer 2002, are one of quantum dots and quantum rods, and are made of one of cesium lead halide and organic ammonium lead halide. The glass panel layer 2003 is disposed on the RGB color filter layer 2002. The upper polarization layer 2004 is disposed on the glass panel layer 2003. In this embodiment, the excitation layer 3, the RGB color filter layer 2002, the glass panel layer 2003 and the upper polarization layer 2004 are arranged in such order along a direction away from the liquid crystal adjustment unit 110.

The light-emitting unit 4 may include a first light-emitting element 41, a second light-emitting element 42 and a circuit board 43. In some embodiments, the first light-emitting element 41 is configured to emit one of a red light or a blue light, and the second light-emitting element 42 is configured to emit the other one of the red light or the blue light. In this embodiment, the first light-emitting element 41 emits the blue light, and the second light-emitting element 42 emits the red light and includes potassium fluorosilicate phosphor. When the lights emitted by the first light-emitting element 41 and the second light-emitting element 42 pass through the liquid crystal adjustment unit 110, and is incident on the excitation layer 3, the quantum structures 31 of the excitation layer 3 are excited by the blue light incident thereon to emit a green light that will pass through the green color filters of the RGB color filter layer 2002, since the quantum structures 31 are registered with the green color filters of the RGB color filter layer 2002. In this embodiment, the light-emitting unit 4 has a structure that is the same as those described in the aforesaid embodiments, and includes a plurality of the first light-emitting elements 41 and a plurality of the second light-emitting elements 42 that are alternatingly arranged on the circuit board 43. Each of the first light-emitting elements 41 may be a light-emitting diode that is capable of emitting a blue light. Each of the second light-emitting elements 42 may be a light-emitting diode that is capable of emitting a red light.

In some embodiments, the liquid crystal adjustment unit 110 is spaced apart from and disposed over the light-emitting unit 4, and the first and second light-emitting elements 41, 42 are located within a projection of the liquid crystal adjustment unit 110 on the light-emitting unit 4. In some embodiments, the liquid crystal adjustment unit 110 further includes a lower polarization layer 1001. In some embodiments, the liquid crystal adjustment unit 110 further includes a thin film transistor (TFT) layer 1002. In some embodiments, the display device further includes a diffusion sheet 8 disposed between the light-emitting unit 4 and the liquid crystal adjustment unit 110. The diffusion sheet 8 has a haze that is larger than 60%.

As shown in FIG. 7, in some embodiments, the excitation layer 3 includes a light-transmissible optical film 33 and a plurality of excitation portions 34 each of which includes the quantum structures (31). The excitation portions 34 are separately disposed within said light-transmissible optical film 33, and are registered with the green color filters of the RGB color filter layer 2002. In certain embodiments, each of the excitation portions 34 may have a strip shape or island shape. The light-transmissible optical film 33 provides support for the excitation portions 34. By virtue of the excitation layer 3 including the light-transmissible optical film 33 and the excitation portions 34, the quantum structures 31 of the excitation layer 3 may be well registered with the green color filters of the RGB color filter layer 2002.

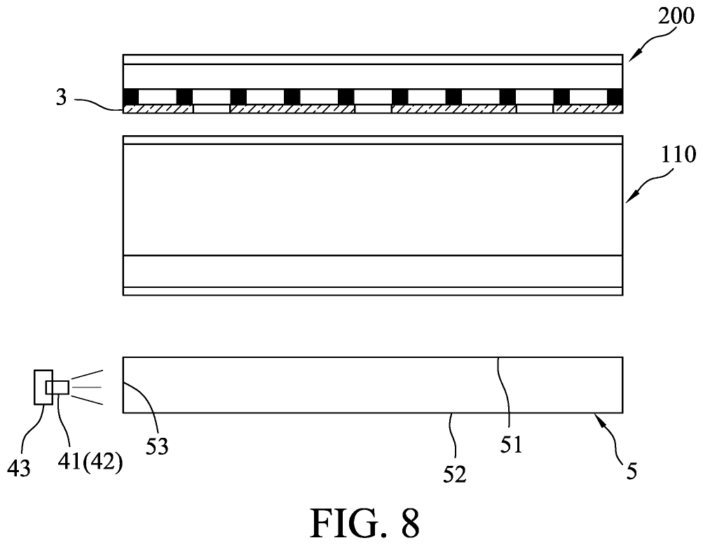

Referring to FIG. 8, in a variation of the display device of the embodiment, the display device further includes a light guide plate 5 disposed on a back side of the liquid crystal adjustment unit 110 opposite to the color filter structure 200. The light guide plate 5 has a light exiting light guide surface 51 facing the back side of the liquid crystal adjustment unit 101, a reflection light guide surface 52 opposite to the light exiting light guide surface 51, and an incident light guide surface 53 interconnecting the light exiting light guide surface 51 and the reflection light guide surface 52. Additionally, the first and second light-emitting elements 41, 42 of the light-emitting unit 4 face the incident light guide surface 53. The blue light emitted by the first light-emitting element(s) 41 and the red light emitted by the second light-emitting element(s) 42 enter the light guide plate 5 through the incident light guide surface 53, and are directed toward the light exiting light guide surface 51 by the reflection light guide surface 52. After exiting the light exiting light guide surface 51, the blue and red lights enter the liquid crystal adjustment unit 110. The reflection light guide surface 52 may be formed with a dot array structure, and is capable of reflecting light. As mentioned above, the light-emitting unit 4 may include a plurality of the first light-emitting elements 41 and a plurality of the second light-emitting elements 42 which are alternatingly arranged along a side of the incident light guide surface 53 of the light guide plate 5 and face the incident light guide surface 53.

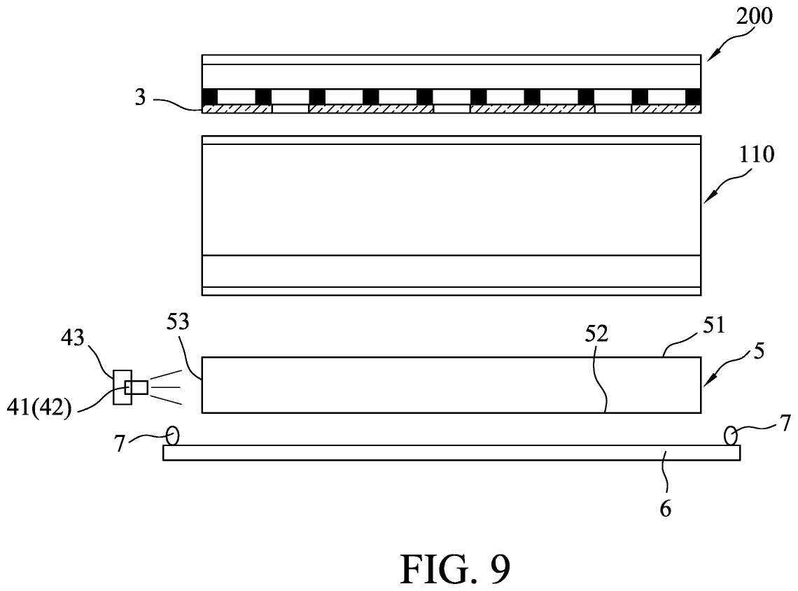

Referring to FIG. 9, the display device may optionally include a reflective sheet 6 and a green phosphor 7. The reflective sheet 6 is disposed on the reflection light guide surface 52 of the light guide plate 5 to reflect the lights leaking through the reflection light guide surface 52 back to the light guide plate 5, so as to reduce light loss and improve the brightness of the display device. The green phosphor 7 may be disposed on the reflective sheet 6. The red and/or blue lights leaking through the reflection light guide surface 52 can excite the green phosphor 7 to emit a green light, which is then directed toward the light guide plate 5 by the reflective sheet 6. As such, a total amount of green light (i.e., the green light emitted by the green phosphor 7 and the quantum structures 31) can be increased, and the problem of an undesired color (such as magenta color) present in the corners and edges of a conventional edge-lit display device can be thus effectively reduced.

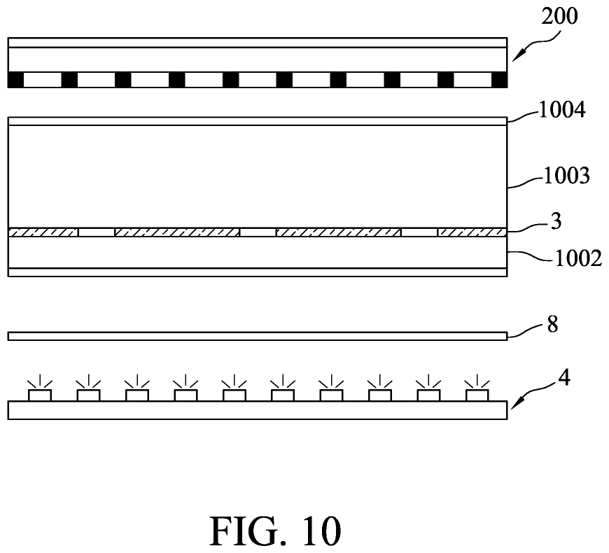

Referring to FIG. 10, in another variation of the display device of the embodiment, the excitation layer 3 is disposed on the liquid crystal layer 1003 opposite to said electrode layer 1004. In some variations, the excitation layer 3 may be disposed between the TFT layer 1002 and the liquid crystal layer 1003. In this embodiment, the display device may also include the light-transmissible optical film 33 to support the excitation layer 3. However, it is noted that the light-transmissible optical film 33 may be omitted in some embodiments.

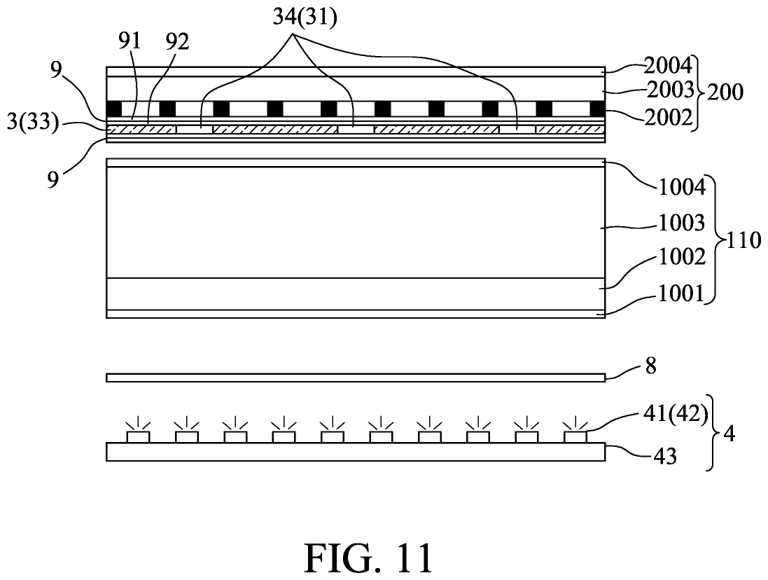

Referring to FIG. 11, in the aforesaid embodiment of the display device and the variations thereof, the display device may further include two water resistance units 9 that are respectively disposed on the two opposite sides of the excitation layer 3 (see FIG. 11). Each of the water resistance units 9 includes a water resistance layer 91 and a combination layer 92.

The combination layers 92 of the water resistance units 9 are respectively formed on the two opposite sides of the excitation layer 3, and may have the same structure, material and function as those described in FIG. 5.

The water resistance layers 91 of the water resistance units 9 are respectively formed on the combination layers 92. More specifically, each of the combination layers (92) is disposed between one of the two opposite sides of the excitation layer 3 and a respective water resistance layer 91 to cover the excitation layer 3. The water resistance layer 91 of each of the water resistance units 9 may have the same structure, material and function as those described in FIG. 5.

The methods for forming the combination layers 92 and the water resistance layers 91 are the same as those described in FIG. 5.

It should be noted that, based on practical requirements, one of the water resistance units 9 may be omitted.

In the description above, for the purposes of explanation, numerous specific details have been set forth in order to provide a thorough understanding of the embodiment(s). It will be apparent, however, to one skilled in the art, that one or more other embodiments may be practiced without some of these specific details. It should also be appreciated that reference throughout this specification to “one embodiment,” “an embodiment,” an embodiment with an indication of an ordinal number and so forth means that a particular feature, structure, or characteristic may be included in the practice of the disclosure. It should be further appreciated that in the description, various features are sometimes grouped together in a single embodiment, figure, or description thereof for the purpose of streamlining the disclosure and aiding in the understanding of various inventive aspects; such does not mean that every one of these features needs to be practiced with the presence of all the other features. In other words, in any described embodiment, when implementation of one or more features or specific details does not affect implementation of another one or more features or specific details, said one or more features may be singled out and practiced alone without said another one or more features or specific details. It should be further noted that one or more features or specific details from one embodiment may be practiced together with one or more features or specific details from another embodiment, where appropriate, in the practice of the disclosure.

While the disclosure has been described in connection with what is(are) considered the exemplary embodiment(s), it is understood that this disclosure is not limited to the disclosed embodiment(s) but is intended to cover various arrangements included within the spirit and scope of the broadest interpretation so as to encompass all such modifications and equivalent arrangements.

What is claimed is:

1. A display device comprising:
a liquid crystal adjustment unit including a liquid crystal layer and an electrode layer disposed on the liquid crystal layer;
a color filter structure disposed on the liquid crystal adjustment unit and including
an RGB color filter layer that has a plurality of red color filters, a plurality of blue color filters, and a plurality of green color filters being spaced apart from each other, and arranged in a matrix pattern,
a light-emitting unit disposed on said liquid crystal adjustment unit opposite to said RGB color filter layer, and including a first light-emitting element emitting a blue light and a second light-emitting element emitting a red light; and
an excitation layer disposed between said color filter structure and said light-emitting unit, spaced apart from said light-emitting unit, and including a plurality of quantum structures, said quantum structures being registered with said green color filters, being one of quantum dots and quantum rods, and being made of one of cesium lead halide and organic ammonium lead halide.

2. The display device as claimed in claim 1, wherein said excitation layer is disposed between said color filter structure and said liquid crystal adjustment unit.

3. The display device as claimed in claim 2, wherein said excitation layer is immediately adjacent to said color filter structure.

4. The display device as claimed in claim 1, wherein said excitation layer is disposed on said liquid crystal layer opposite to said electrode layer.

5. The display device as claimed in claim 4, wherein said excitation layer is closer to said light-emitting unit than said electrode layer.

6. The display device as claimed in claim 1, wherein said liquid crystal adjustment unit further includes a TFT layer, said excitation layer being disposed between said TFT layer and liquid crystal layer.

7. The display device as claimed in claim 6, wherein:
said color filter structure further includes a glass panel layer that is disposed on said RGB color filter layer, and an upper polarization layer that is disposed on said glass panel layer; and
said liquid crystal adjustment unit further includes a lower polarization layer that is disposed on said TFT layer opposite to said excitation layer.

8. The display device as claimed in claim 1, wherein said first light-emitting element and said second light-emitting element are located within a projection of said liquid crystal adjustment unit on said light-emitting unit.

9. The display device as claimed in claim 3, further comprising a diffusion sheet disposed between said light-emitting unit and said liquid crystal adjustment unit, said diffusion sheet having a haze that is larger than 60%.

10. The display device as claimed in claim 1, wherein:
said display device further comprises a light guide plate disposed on a back side of said liquid crystal adjustment unit:
said light guide plate has a light exiting light guide surface facing said back side of said liquid crystal adjustment unit, a reflection light guide surface opposite to said light exiting light guide surface, and an incident light guide surface interconnecting said light exiting light guide surface and said reflection light guide surface,
said first light-emitting element and said second light-emitting element of said light-emitting unit face said incident light guide surface.

11. The display device as claimed in claim 1, wherein said excitation layer includes a light-transmissible optical film and an excitation portion disposed within said light-transmissible optical film.

12. The display device as claimed in claim 1, further comprising at least one water resistance unit that covers said excitation layer, said at least one water resistance unit including a water resistance layer that is made of an organic material and an inorganic material and that is moisture impermeable.

13. The display device as claimed in claim 12, wherein said at least one water resistance unit further includes a combination layer that is disposed between said excitation layer and said water resistance layer to cover said excitation layer.

14. The display device as claimed in claim 13, wherein said combination layer is made of an organic material.

15. The display device as claimed in claim 14, wherein said organic material of said combination layer is one of methyl methacrylate, epoxy methacrylate, epoxy acrylates, bisphenol A ethoxylate dimethacrylate, hexanediol diacrylate, bisphenol A epoxy acrylate, or combinations thereof.

16. The display device as claimed in claim 10, further comprising a reflective sheet disposed on the reflection light guide surface of the light guide plate.

17. The display device as claimed in claim 16, further comprising a green phosphor disposed on said reflective sheet.

18. The display device as claimed in claim 1, wherein said second light-emitting element is a red light-emitting diode including potassium fluorosilicate phosphor.

19. The display device as claimed in claim 18, wherein said quantum structures are quantum dots, each with a dimension ranging from 9 nm to 13 nm.

20. The display device as claimed in claim 19, wherein said quantum structures emit a green light with a dominant wavelength ranging from 520 nm to 540 nm.
